(19) United States
(12) Patent Application Publication
(10) Pub. No.: US 2023/0317406 A1
(43) Pub. Date: Oct. 5, 2023

(54) Charged Particle Beam System

(71) Applicant: Hitachi High-Tech Corporation, Tokyo (JP)

(72) Inventors: Yuto KAWASHIMA, Tokyo (JP); Satoru YAMAGUCHI, Tokyo (JP); Yasunori TAKASUGI, Tokyo (JP)

(21) Appl. No.: 18/127,864

(22) Filed: Mar. 29, 2023

(30) Foreign Application Priority Data
Mar. 31, 2022 (JP) 2022-060378

(51) Int. Cl. H01J 37/21; H01J 37/244; H01J 37/28

(52) U.S. Cl. CPC H01J 37/21; H01J 37/244; H01J 37/28; H01J 2237/2448; H01J 2237/216; H01J 2237/24578; H01J 37/1472

(57) ABSTRACT

A charged particle beam system that improves throughput by applying an approximate expression created using a wafer to be actually measured is provided. The invention is directed to a charged particle beam system including a charged particle beam device that includes a detector configured to detect a signal particle obtained by irradiating a sample with a charged particle beam and a computer system that controls an operation of the charged particle beam device, in which the computer system executes a process of performing autofocus on each of a plurality of peripheral AF points set in the sample and outside a measurement area, and acquiring focus information of the plurality of AF points, a process of approximating focus distribution within the measurement area based on the focus information of the plurality of peripheral AF points, and a process of measuring each measurement point within the measurement area of the same sample as the sample from which the focus information is acquired, using the approximated focus distribution.

### TECHNICAL FIELD

The embodiment relates to a charged particle beam system.

### BACKGROUND ART

In a general length measurement SEM, an approximate expression (focus distribution) is created in advance when executing autofocus (AF) processing in a measurement area, and AF processing is executed based on the approximate expression. The approximate expression is usually created by measuring a length of a wafer for approximation with the length measurement SEM. During actual length measurement processing, an approximate value (calculated by applying coordinates of a measurement point to the approximate expression) by the approximate expression created in advance is set to a focus parameter, and a measurement operation is performed after the AF processing is executed based on the focus parameter.

### CITATION LIST

### Patent Literature

PTL 1: JP2012-146581A

### SUMMARY OF INVENTION

### Technical Problem

However, in recent years, there is a strong demand for improvement in throughput of multi-point measurement processing in the length measurement SEM. For that reason, when the inventors closely examined the processing time per measurement point, it was found that the time required for autofocus (AF) processing was dominant. In AF processing, since an electron beam is scanned in a pattern while changing a value for controlling a focus position, an image evaluation value is calculated for each obtained image, the vicinity where the evaluation value becomes the maximum is detected as a focusing position, and a control value is set, processing time is needed.

In the general length measurement SEM described above, when measuring respective length measurement points (tens of thousands of points) in the measurement area, AF processing should be performed at the respective length measurement points, and an enormous amount of time is consumed by this AF processing. Accordingly, AF processing is a factor that hinders improvement in throughput. The reason why the AF processing should be executed again at each length measurement point is that accuracy of the approximate expression created in advance is insufficient and a wafer used for creating the approximate expression is different from a wafer to be actually measured.

In view of such circumstances, the present disclosure proposes a technique for improving throughput by applying an approximate expression created using the wafer to be actually measured.

### Solution to Problem

In order to solve the problems described above, the present disclosure proposes, as an example, a charged particle beam system including a charged particle beam device including a detector configured to detect a signal particle obtained by irradiating a material with a charged particle beam and a computer system that controls an operation of the charged particle beam device, in which the computer system executes a process of performing autofocus on each of a plurality of peripheral AF points set in the sample and outside a measurement area, and acquiring focus information of the plurality of AF points, a process of approximating focus distribution within the measurement area based on the focus information of the plurality of peripheral AF points, and a process of measuring each measurement point within the measurement area of the same sample as the sample from which the focus information is acquired, using the approximated focus distribution.

Further features related to the present disclosure will become apparent from the description of this specification and the accompanying drawings. In addition, aspects of the present disclosure will be achieved and realized by means of elements and combinations of various elements and aspects of the following detailed description and appended claims.

It should be understood that the description herein is merely exemplary and is not intended in any way to limit the claims or application examples of this disclosure.

### Advantageous Effects of Invention

According to the technique of the present disclosure, throughput can be dramatically improved.

### BRIEF DESCRIPTION OF DRAWINGS

FIG. 1 is a diagram illustrating a schematic configuration example of a length measurement system 100 according to this embodiment.

FIG. 2 is a diagram illustrating a principle and outline of length measurement processing according to this embodiment.

FIG. 3A is a diagram illustrating an AF point setting mode (4-point mode) for setting four AF points.

FIG. 3B is a diagram illustrating an AF point setting mode (5-point mode) for setting five AF points.

FIG. 3C is a diagram illustrating an AF point setting mode (8-point mode) for setting eight AF points.

FIG. 3D is a diagram illustrating an AF point setting mode (9-point mode) for setting nine AF points.

FIG. 4 is a diagram illustrating a table in which contents of the 4-point mode to the 9-point mode are arranged.

FIG. 5 is a diagram illustrating processing when AF processing (focus information acquisition processing) fails at an AF point set (selected) by an operator.

FIG. 6 is a diagram illustrating an example of a processing sequence of AF points (for 9-point mode).

FIG. 7 is a diagram illustrating a relationship between focus distribution within a wafer and the degree (first order, second order, or higher order) of an approximate expression.

FIG. 8 is a flowchart illustrating an entire out-of-measurement-area AF recipe process in which an approximate expression is created by inserting a wafer into a length measurement SEM and executing AF processing, a length of the wafer is measured (measured) as it is.

FIG. 9 is a flowchart illustrating details of out-of-measurement-area AF processing illustrated in step 802 of FIG. 8.

FIG. 10 is a flowchart illustrating the out-of-measurement-area AF recipe process accompanying update of focus distribution.

FIG. 11 is a diagram illustrating a configuration example of an AF point setting graphical user interface (GUI) 1100 for setting AF points for executing the out-of-measurement-area AF processing according to this embodiment.

### DESCRIPTION OF EMBODIMENTS

This embodiment discloses a technique for calculating focus distribution (approximate expression) in a measurement area of a wafer to be measured (shot, chip, cell, mat, and the like) using focus information of set points (several points) of the wafer acquired by performing AF processing on the set points, and measuring each measurement point by applying coordinate values of each measurement point to the approximate expression. By doing so, throughput can be dramatically improved. Details of this embodiment will be described below.

<Configuration Example of Length Measurement System>

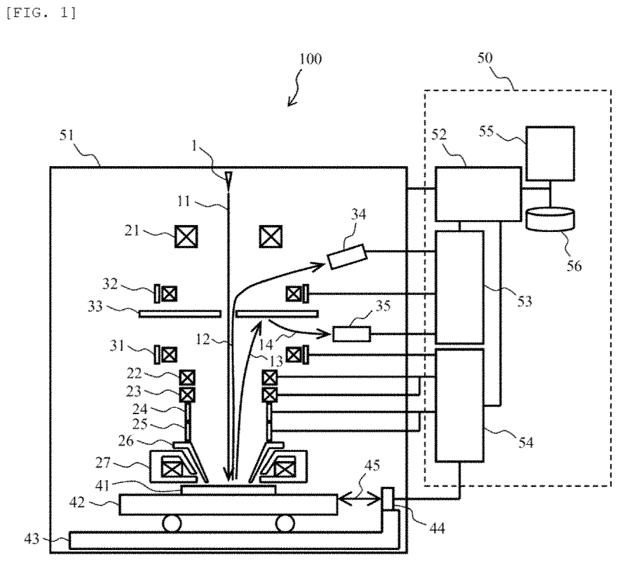

FIG. 1 is a diagram illustrating a schematic configuration example of the length measurement system 100 according to this embodiment.

The length measurement system 100 includes a computer system 50 and a length measurement SEM device 51. The computer system 50 includes an overall control unit 52, a signal processing unit 53, a deflector control processing unit 54, an input and output unit 55, and a storage unit 56. The length measurement SEM device 51 includes an electron source 1, a condenser lens 21, an upper stage primary electron deflector 22, a lower stage primary electron deflector 23, an upper stage scanning deflector 24, a lower stage scanning deflector 25, a rear stage acceleration electrode 26, an objective lens 27, a lower secondary electron deflector 31, an upper secondary electron deflector 32, a secondary electron diaphragm 33, an upper detector 34, a lower detector 35, a stage 42, a stage conveyance base 43, and a position detection unit 44.

In the length measurement SEM device 51, primary electrons 11 are generated from the electron source 1. The primary electrons 11 are focused by the condenser lens 21 and deflected by the upper stage scanning deflector 24 and the lower stage scanning deflector 25 so as to two-dimensionally scan a sample 41. The deflected primary electrons 11 are accelerated by the rear stage acceleration electrode 26 and then focused on the sample 41 by the objective lens 27. An example of the objective lens 27 in this embodiment being an electromagnetic lens that controls focus by an exciting current is illustrated, but it may be an electrostatic lens or a composite of an electromagnetic lens and an electrostatic lens.

Secondary electrons are generated from an irradiation position of the primary electrons 11 on the sample 41. In the secondary electrons, surface information of the sample 41 or the like is contained. Therefore, information on the surface of the sample 41 can be obtained by irradiating an any position on the sample 41 with the primary electrons 11 and detecting information on the secondary electrons.

Among the generated secondary electrons, secondary electrons 12 with a high elevation angle close to 90° pass through the secondary electron diaphragm 33, are deflected by the upper secondary electron deflector 32, and are converted into electrical signals by the upper detector 34. On the other hand, secondary electrons 13 with a smaller elevation angle than that of the secondary electrons 12 collide with the secondary electron diaphragm 33. Then, tertiary electrons 14 are generated from the secondary electron diaphragm 33, detected by the lower detector 35, and converted into an electrical signal.

Electrical signals from the upper detector 34 and the lower detector 35 are sent to the signal processing unit 53. The signal processing unit 53 integrates signal intensities in synchronization with the two-dimensional scanning and generates an image in which each signal intensity is mapped, and the image is output to the input and output unit 55 through the overall control unit 52.

The sample 41 is placed on the stage 42 that can move in a two-dimensional direction. This is for irradiating any coordinates on the sample 41 with the primary electrons 11. The position of the stage 42 is measured in real time with a position detection laser 45 by a laser interferometer of the position detection unit 44 installed on the stage conveyance base 43. The positioning method in the position detection unit 44 is not limited to the laser interferometer as described above, and the same effect can be obtained with a linear scale. By operating the stage 42, irradiation of the any coordinates with the primary electrons 11 is realized.

Furthermore, by deflecting the primary electrons 11 with the upper stage primary electron deflector 22 and the lower stage primary electron deflector 23, it is possible to control the irradiation of a target position with the primary electrons 11. The upper stage primary electron deflector 22 and the lower stage primary electron deflector 23 may be electrostatic deflectors or electromagnetic deflectors. Each of the upper stage scanning deflector 24 and the upper stage primary electron deflector 22, and each of the lower stage scanning deflector 25 and the lower stage primary electron deflector 23 can be respectively controlled as one deflector.

In general, the stage operation can move over a wide range, but alignment accuracy is poor, and primary electron deflection control has a narrow movement range, but the alignment accuracy is high. Therefore, in order to irradiate the target position coordinates on the sample designated by the user with the primary electrons 11, a combination of both of these controls is performed. In this case, stage position information obtained from the position detector 44 is input to the deflector control processing unit 54 in order to prevent a primary electron irradiation position from fluctuating due to vibration or drift of the stage 42. The deflector control processing unit 54 calculates a primary electron deflection amount such that the primary electron irradiation position on the sample 41 does not change, and controls the upper stage primary electron deflector 22 and the lower stage primary electron deflector 23. This control can also be performed by the upper stage scanning deflector 24 and the lower stage scanning deflector 25 in the same manner.

The AF processing is processing for scanning the sample 41 with the electron beam while changing an excitation current value of the objective lens 27, calculating an image evaluation value by the signal processing unit 53 for each obtained image, and feeding back a corresponding excitation current value to the objective lens 27 with the vicinity of the maximum evaluation value as the focusing position.

<Principle and Overview of Length Measurement Processing According to this Embodiment>

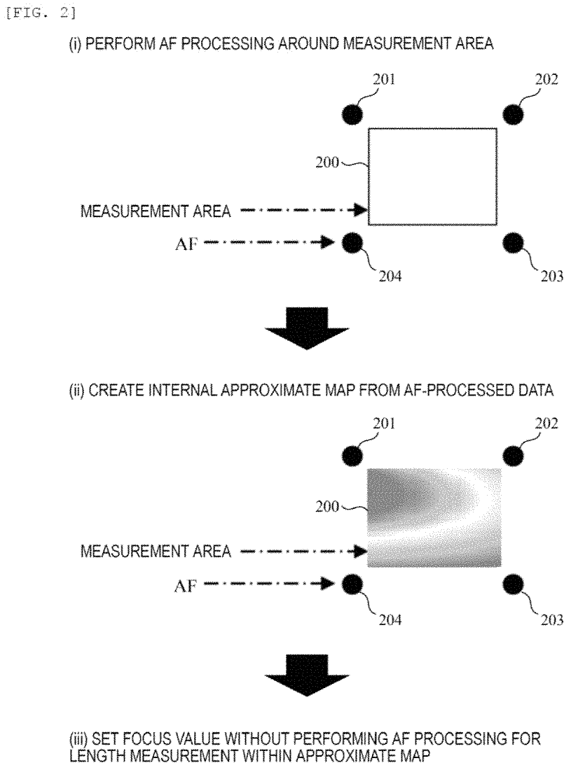

FIG. 2 is a diagram illustrating the principle and outline of length measurement processing according to this embodiment.

(i) Autofocus (AF) Processing Around Measurement Area (Upper Part of FIG. 2)

A user (operator) first sets a plurality of AF points (1) around a measurement area 200 or (2) around the measurement area 200 and within the measurement area 200. This AF point means a point on which the autofocus processing is actually performed and for which focus information (height and potential: focus parameters) is acquired.)

(ii) Creation of Focus Distribution (Approximate Map) (Middle Part of FIG. 2)

The focus distribution (approximate expression) is created using focus information (focus parameter) of each AF point. The focus distribution has a different degree of polynomial depending on a set number of AF points. For example, if the number of AF points is 4 or 5, it can be a linear expression (approximate expression=a*x+b*y+c), and if the number of AF points is 8 or 9, it can be a linear expression or quadratic expression (approximate expression=a+b*x+c*y+d*x2+e*x*y+f*y2).

As the approximate expression, a linear regression model of n-th order can be used depending on the number of AF points, and a Bayesian optimization algorithm can also be used assuming that the focus information for each AF point follows a Gaussian process.

(iii) Execution of Length Measurement Processing within Measurement Area (Lower Part of FIG. 2: Explanation Only)

Within the measurement area 200, AF processing is not performed at each measurement point (synonymous with length measurement point), and the focus parameter are set with reference to the focus distribution (approximate expression/approximate map). That is, a voltage value and a current value to be applied to each deflector are set based on the focus parameter calculated by applying the coordinate value of the measurement point to the approximate expression. With this configuration, there is no need to perform AF processing when actually measuring tens of thousands of measurement points within the measurement area 200 (AF processing only needs to be performed for a few points for focus distribution creation), and the length measurement processing can be executed in an overwhelmingly short time (throughput improvement) compared to the related technology in which AF processing should be performed on all measurement points.

<AF Point Setting Mode in Out-of-Measurement-Area AF Processing>

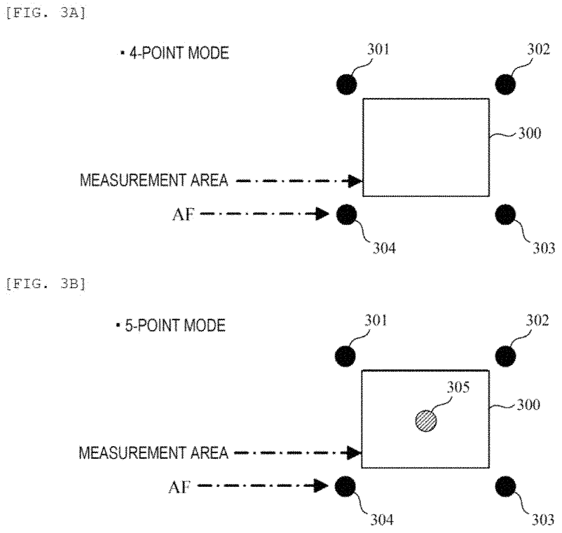

FIG. 3 is a diagram illustrating an AF point setting mode for executing AF processing according to this embodiment. FIG. 3A is a diagram illustrating a 4-point mode for setting four AF points, FIG. 3B is a diagram illustrating a 5-point mode for setting five AF points, FIG. 3C is a diagram illustrating an 8-point mode for setting eight AF points, and FIG. 3D is a diagram illustrating a 9-point mode for setting nine AF points. Although the mode in which four to nine AF points are set is illustrated here, the number of AF points is not limited to these set numbers, and the number of AF points can be increased (the more AF points, the better the approximation accuracy) depending on the type of wafer, length measurement conditions, allowable throughput, and like.

(i) 4-Point Mode (FIG. 3A)

The 4-point mode is, for example, a mode which is used in cell units of wafer and in which four AF points 301 to 304 are set around a measurement area 300. This 4-point mode can be applied to a wafer which is susceptible to a charged particle beam (for example, electron beam) (easily electrified by electron beam). The approximate expression that can be created in the 4-point mode is a linear expression, and the focus distribution (approximate expression) is expressed by a*x+b*y+c as described above.

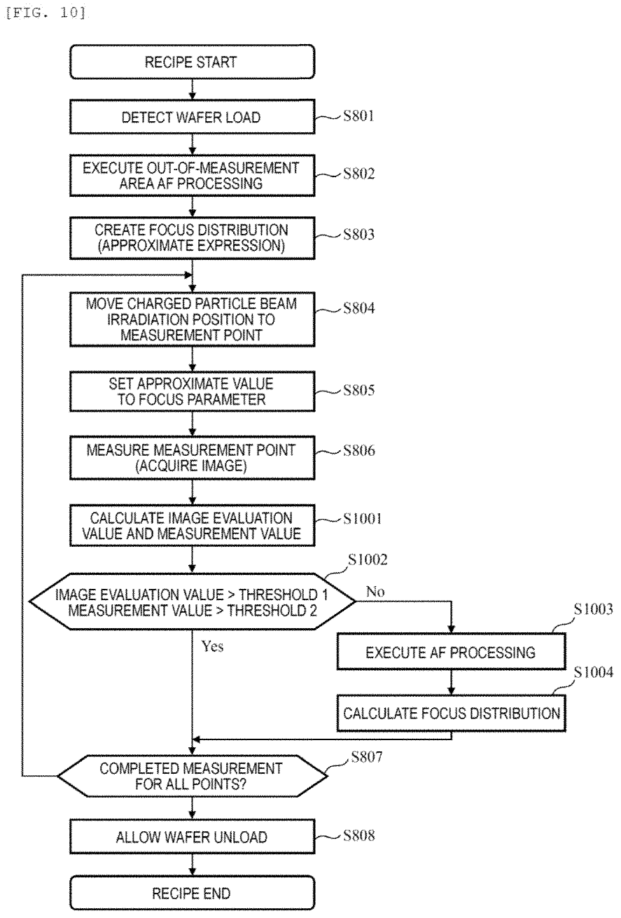

Since a system cannot determine whether or not the wafer is susceptible to the charged particle beam, the user (operator) selects whether to obtain the focus distribution in the 4-point mode or the 5-point mode (FIG. 3B) (The same applies to the selection of the 8-point mode (FIG. 3C) and 9-point mode (FIG. 3D), which will be described later).

(ii) 5-Point Mode (FIG. 3B)

The 5-point mode is, for example, a mode which is used in cell units of wafer, and in which four AF points 301 to 304 are set around the measurement area 300 and one AF point 310 is set within the measurement area 300. This 5-point mode can be applied to the wafer that is not susceptible to a charged particle beam (for example, electron beam) (difficult to be electrified by electron beam). Since the AF point can be set within the measurement area 300, it is possible to create focus distribution (approximate expression) with higher accuracy than in the 4-point mode. The approximate expression that can be created in the 5-point mode is also a linear expression as in the 4-point mode, and the focus distribution (approximate expression) is expressed by a*x+b*y+c as described above.

(iii) 8-Point Mode (FIG. 3C)

The 8-point mode is, for example, a mode which is used in chip units of wafer and in which eight AF points 301 to 308 are set around the measurement area 300. This 8-point mode can be applied to a wafer which is susceptible to a charged particle beam (for example, electron beam) (easily electrified by electron beam). The approximate expression that can be created in the 8-point mode is a linear or quadratic expression, and the focus distribution (approximate expression) is expressed by a*x+b*y+c, or a+b*x+c*y+d*x2+e*x*y+f*y2 as described above.

(iv) 9-Point Mode (FIG. 3D)

The 9-point mode is, for example, a mode which is used in chip units of wafer, and in which eight AF points 301 to 308 are set around the measurement area 300 and one AF point 310 is set within the measurement area 300. This 9-point mode can be applied to the wafer that is not susceptible to a charged particle beam (for example, electron beam) (difficult to be electrified by electron beam). Since the AF point can be set within the measurement area 300, it is possible to create focus distribution (approximate expression) with higher accuracy than in the 8-point mode. The approximate expression that can be created in the 9-point mode is also a linear or quadratic expression as in the 9-point mode, and the focus distribution (approximate expression) is expressed by a*x+b*y+c, or a+b*x+c*y+d*x2+e*x*y+f*y2 as described above.

(v) Summary of AF Point Setting Mode

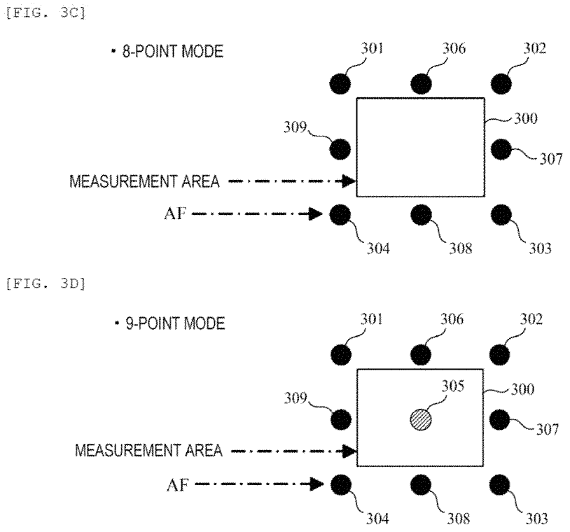

FIG. 4 is a diagram illustrating a table in which the contents of the 4-point mode to the 9-point mode described above are arranged.

As illustrated in FIG. 4, when the AF points are set for in cell units and the length of the cell is measured, the 4-point mode or the 5-point mode is used depending on the property (easiness of electrification) of the wafer. In the 5-point mode, an AF point is set in the center (not necessarily in the center) of the measurement area 300 in addition to the four AF points around the measurement area 300 set in the 4-point mode. Here, one AF point is set within the measurement area 300, but two or more points may be set depending on the trade-off between throughput and length measurement accuracy. In the case of the cell, since the measurement area 300 is smaller than that of the chip, the number of AF points to be set is small, and only a linear approximate expression is possible.

When AF points are set in chip units and the length of the chip is measured, the 8-point mode or the 9-point mode is used depending on the property (easiness of electrification) of the wafer. In the 9-point mode, an AF point is set in the center (not necessarily in the center) of the measurement area 300 in addition to the eight AF points around the measurement area 300 set in the 8-point mode. Here, one AF point is set within the measurement area 300, but two or more points may be set depending on the trade-off between throughput and length measurement accuracy. In the case of the chip, since the measurement area 300 is larger than that of the cell, the number of AF points to be set can be increased, and the approximate expression can be a linear or quadratic expression.

<Processing when AF Processing Fails>

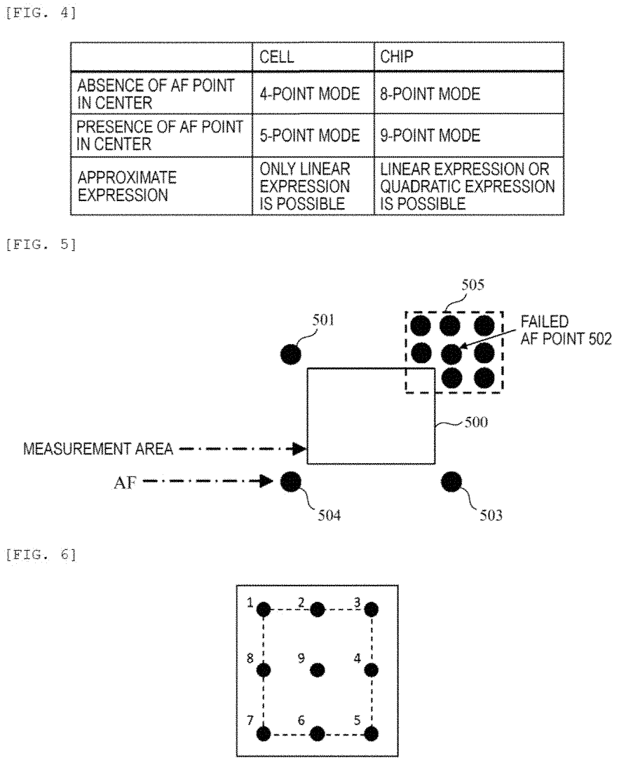

FIG. 5 is a diagram illustrating processing when AF processing (focus information acquisition processing) fails at an AF point set (selected) by an operator.

When AF processing fails (for example, when AF processing fails at an AF point 502) due to reasons such as the absence of a pattern that can be subjected to AF processing at a plurality of AF points 501 to 504 set around a measurement area 500, the overall control unit 52 executes AF processing in a nearby region 505 (for example, a point outside the measurement area 500 and within 10 pixels from the failed AF point 502) of the failed AF point 502. Then, the overall control unit 52 creates an approximate expression to be applied in the measurement area 500 from the acquired focus value. When the focus information cannot be acquired even after AF processing is executed again in the nearby region 505, the nearby region 505 may be further extended until the AF processing is successful.

Similarly, when the AF processing fails at an AF point which is set within the measurement area 500, AF processing is performed in a nearby region (for example, points within 10 pixels from the failed AF point) of the failed AF point, and a focus value is acquired (not illustrated in FIG. 5).

<Processing Sequence of AF Points>

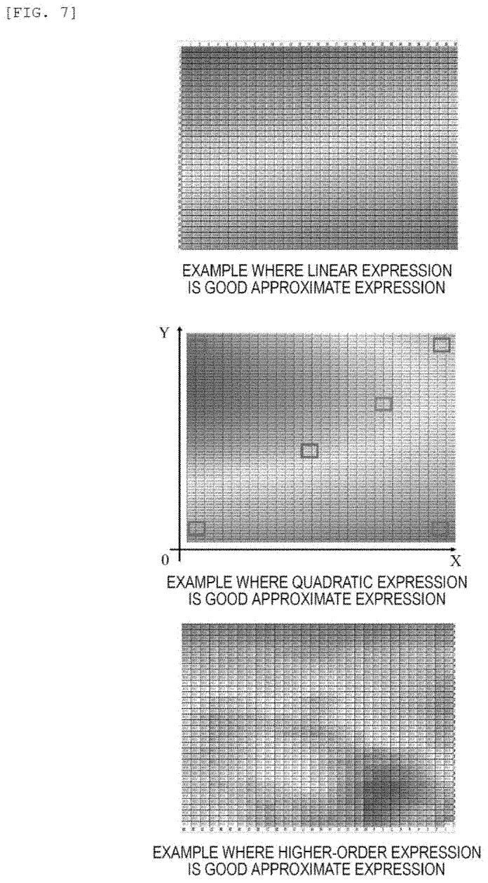

FIG. 6 is a diagram illustrating an example of a processing sequence of AF points (in the case of 9-point mode).

As illustrated in FIG. 6, the order of AF processing can be set, for example, so that the AF processing is sequentially executed for respective AF points around the measurement area clockwise from the AF point set at the upper left of No. 1 and finally AF processing is executed on the AF point within the measurement area. However, the order of AF processing is not limited to this processing sequence, and basically AF processing can be performed in any order, but it is more efficient to set the processing sequence so that a movement distance is as short as possible (AF processing is completed in a short time).

<Relationship Between Focus Distribution within Wafer and Degree of Approximate Expression>

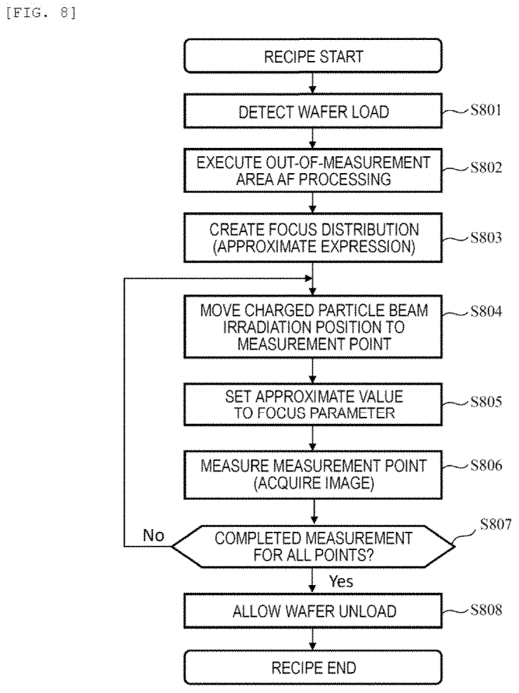

FIG. 7 is a diagram illustrating a relationship between focus distribution within a wafer and the degree (first order, second order, or higher order) of an approximate expression.

The focus distribution indicating the distribution of focus information (height and potential) within the wafer can be known to some extent before length measurement depending on a type of wafer. That is, depending on the type of wafer, it is known in advance whether variation in the focus distribution is uniform (first order approximate expression is suitable), whether there is a certain regularity (second order approximate expression is suitable) in the variation in the focus distribution within the wafer, or whether the variation is random (higher order approximate expression is suitable).

As illustrated in the upper part of FIG. 7, when the variation in the focus distribution within the wafer is uniform (monotonic), the degree of the approximate expression can be set as a first order. When the variation in the focus distribution is uniform in this way, the 4-point mode or the 5-point mode can be selected as described above.

As illustrated in the middle part of FIG. 7, when there is a certain regularity in the variation in the focus distribution within the wafer, the degree of the approximate expression can be set as a second order. When there is regularity in the variation in the focus distribution in this way, the 8-point mode or the 9-point mode can be selected as described above.

Furthermore, as illustrated in the lower part of FIG. 7, when the variation in the focus distribution within the wafer is relatively random, the degree of the approximate expression can be set as a higher order. When there is regularity in the variation in the focus distribution in this way, a multi-point mode in which more AF points are set than in the 8-point mode or the 9-point mode can be selected.

<Out-of-Measurement-Area AF Recipe Process: Entire Process>

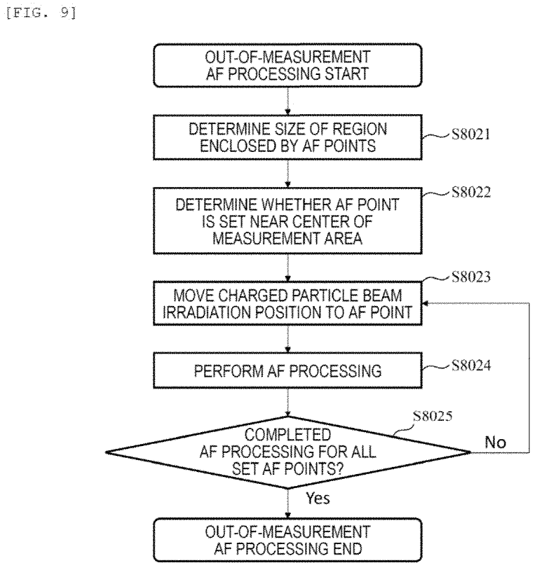

FIG. 8 is a flowchart illustrating an entire out-of-measurement-area AF recipe process in which an approximate expression is created by inserting a wafer into the length measurement SEM and executing AF processing, and a length of the wafer is measured (measured) as it is. In the explanation of processing of each step below, the overall control unit 52 is an operation entity, but the computer system 50 may be the operation entity.

(i) Step 801

When an operator (user) puts a wafer into a length measurement SEM 51, the overall control unit 52 detects that the wafer is put in and starts the recipe process.

(ii) Step 802

The overall control unit 52 executes out-of-measurement-area AF processing (executes AF processing for each set AF point). Each AF point set by the user is focused, and focus information and image information of the point are acquired. Details of step 802 will be described later with reference to FIG. 9.

(iii) Step 803

The overall control unit 52 creates the focus distribution (approximate expression) within the measurement area 300 based on the focus information (including focus value, coordinate value, and the like of each AF point) of the AF points (in the case of 5-point mode or 9-point mode, including the AF point within the measurement area 300) set around the measurement area 300 acquired in step 802.

Specifically, the overall control unit 52 sets a focus distribution expression (template) according to the degree of the approximate expression (it may be specified by the user, or may be determined in advance corresponding to an out-of-measurement-area AF mode (4-point mode to 9-point mode, and the like)), that is, f(x, y)=a*x+b*y+c, or f(x, y)=a+b*x+c*y+d*x2+e*x*y+f*y2), and the like. Next, the overall control unit 52 applies the focus information and image information of each AF point acquired in step 802 to the focus distribution expression (template), calculates each coefficient of the focus distribution expression, and creates a focus distribution (approximate expression) to be used in current length measurement processing for the measurement area 300.

(iv) Step 804

The overall control unit 52 controls the upper stage primary electron deflector 22 and/or the lower stage primary electron deflector 23 (through the deflector control processing unit 54), and/or the stage 42 and moves the charged particle beam (for example, electron beam) irradiation position to the measurement point to be measured (the first measurement point for initial processing) within the measurement area 300.

(v) Step 805

The overall control unit 52 applies the coordinates of the measurement point to the approximate expression created in step 803, and sets a focus parameter (voltage value or current value) at the measurement point.

(vi) Step 806

The overall control unit 52 applies the focus parameter set in step 805 to the upper stage primary electron deflector 22 and/or the lower stage primary electron deflector 23 through the deflector control processing unit 54, and measures the measurement point.

(vii) Step 807

The overall control unit 52 determines whether the measurement processing for all measurement points within the measurement area 300 has been completed. When the measurement processing has been completed for all measurement points (Yes in step 807), the process proceeds to step 808. When an unmeasured point remains within the measurement area 300 (No in step 807), the process proceeds to step 804.

(viii) Step 808

The overall control unit 52, for example, outputs a predetermined display to the input and output unit 55 of the computer system 50 and notifies the operator that the measurement (length measurement) of the measurement area 300 has been completed. The operator who receives this notification can take out the measured wafer from the length measurement SEM 51.

<Step 802: Details of Out-of-Measurement Area AF Processing>

FIG. 9 is a flowchart illustrating details of the out-of-measurement-area AF processing illustrated in step 802 of FIG. 8.

(i) Step 8021

For example, the operator sets a plurality of AF points around the outside of the measurement area 300 on the GUI displayed on a display screen. When the wafer to be measured is susceptible to electrification, the AF point is not set within the measurement area 300 (4-point mode, 8-point mode, and the like). On the other hand, when the wafer to be measured is less susceptible to electrification, the AF point can be set within the measurement area 300 (5-point mode, 9-point mode, and the like). If an object to be measured is a wafer chip, the 8-point mode or 9-point mode is applied. If the object to be measured is a wafer cell, the 4-point mode or 5-point mode is applied.

The overall control unit 52 calculates a size (for example, size determination based on four points of corners) of a region surrounded by the AF points set by the operator and determines whether the object to be measured is a chip or a cell.

The overall control unit 52 may, for example, determine the size of the region determined from the AF points (4 points of the corners around the outside of the measurement area 300) initially set by the operator, and determine whether a set number of AF points is appropriate for the size of the region (is the set number sufficient?). For example, a threshold of the set number is provided for each size, and when the set number is greater than the threshold, it can be determined that the set number of AF points is appropriate. Then, when it is determined that the set number is not sufficient, the overall control unit 52 can output (display) a notification (alarm) for urging setting of more AF points to the input and output unit 55.

(ii) Step 8022

The overall control unit 52 determines whether the AF point is set by an operator near the center of the measurement area 300 (not necessarily set in the center as long as it is within the measurement area 300). When the AF point is set within the measurement area 300, the point is subject to AF processing even within the measurement area 300.

(iii) Step 8023

The overall control unit 52 controls the upper stage primary electron deflector 22 and/or the lower stage primary electron deflector 23 through the deflector control processing unit 54 and moves (irradiation position alignment) the charged particle beam (for example, electron beam) to the set AF point (the first AF point for initial AF processing).

(iv) Step 8024

The overall control unit 52 performs autofocus processing (AF processing) on the AF point for which the irradiation position alignment was performed in step 8023, and acquires focus information on the AF point.

(v) Step 8025

The overall control unit 52 determines whether AF processing has been completed for all set AF points. When AF processing has been completed for all AF points (Yes in step 8025), the out-of-measurement-area AF processing ends. On the other hand, when there is an AF point for which AF processing has not been completed (No in step 8025), the process proceeds to step 8023.

<Out-of-Measurement Area AF Recipe Process Accompanying Update of Focus Distribution>

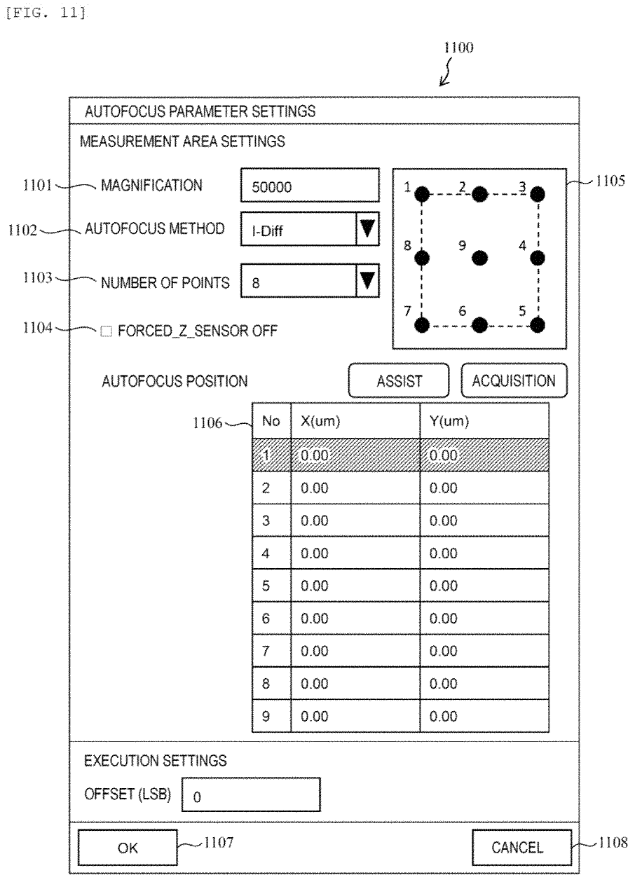

FIG. 10 is a flowchart illustrating the out-of-measurement-area AF recipe process accompanying update of focus distribution. More specifically, the process of FIG. 10 is a process of measuring all the measurement points while updating the focus distribution (approximate expression), which is once created using the focus information of each AF point acquired by the out-of-measurement-area AF processing as necessary, based on the measurement result of the measurement point within the measurement area 300, in the entire process of FIG. 8.

(i) Steps 801 through 808

Steps 801 to 808 are the same as steps 801 to 808 in FIG. 8, and thus the description thereof will be omitted.

(ii) Step 1001

The overall control unit 52 calculates the image evaluation value (for example, luminance value) and the measurement value (for example, length measurement value) of the measurement point being subjected to the processing using the measurement value (image) acquired using the current focus distribution (approximate expression).

(iii) Step 1002

The overall control unit 52 determines whether or not the image evaluation value and the measurement value calculated in step 1001 are greater than the corresponding threshold 1 and threshold 2, respectively. That is, in this step, it is determined whether image quality of the acquired image is sufficiently good.

When the image evaluation value is greater than threshold 1 and the measured value is greater than threshold 2 (Yes in step 1002), the process proceeds to step 807. On the other hand, when the image evaluation value is equal to or less than threshold 1 or the measurement value is equal to or less than threshold 2 (No in step 1002), the process proceeds to step 1003.

(iii) Step 1003

The overall control unit 52 performs AF processing on the measurement point currently being measured, and acquires new focus information.

(iv) Step 1004

The overall control unit 52 updates the previously created focus distribution (approximate expression) using the focus information (including focus value, coordinate value, and the like) of the measurement point, which is being measured, acquired in step 1003. The update of the focus distribution may be performed, for example, using the newly acquired focus information, the previously acquired AF point, and the past measurement point (if any) used for updating the focus distribution, and may be performed using only the AF point and the focus information of the measurement point acquired by the current AF processing.

As described above, since the measurement processing is executed while updating the focus distribution, a high accuracy image can be acquired by the optimum focus distribution, and improvement of throughput can also be realized.

<GUI Configuration Example>

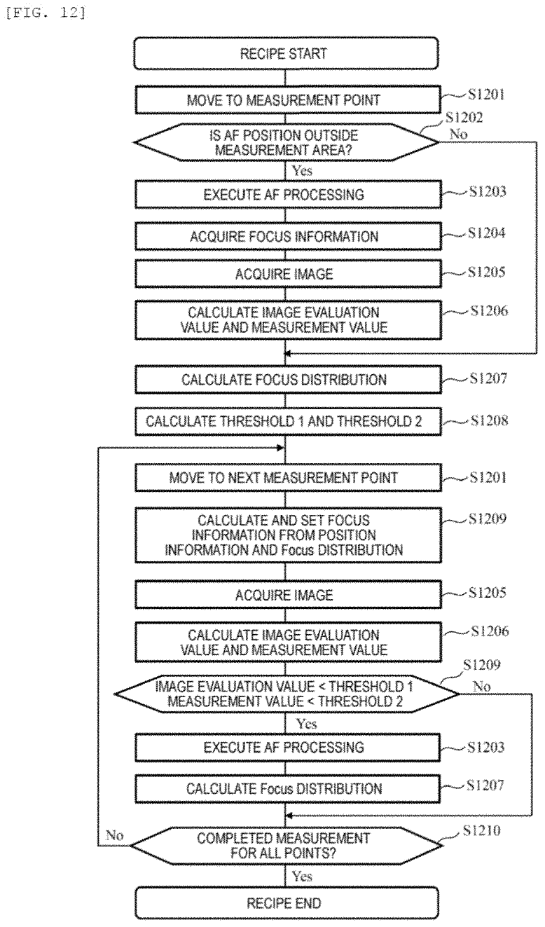

FIG. 11 is a diagram illustrating a configuration example of an AF point setting graphical user interface (GUI) 1100 for setting AF points for executing the out-of-measurement-area AF processing according to this embodiment.

The AF point setting GUI 1100 includes, for example, a magnification setting field 1101, an autofocus method setting field 1102, an AF point number setting field 1103 for inputting the number of AF points, a Forced Z Sensor setting field 1104 for turning ON/OFF an operation of a height detection sensor, an AF processing sequence display field 1105, an AF point coordinate setting field 1106, an OK button 1107, and a Cancel button 1108, as configuration items;

In the AF point setting GUI 1100, a configuration in which the number of coordinates that can be input in the AF point coordinate setting field 1106 is the same as the numerical value input in the AF point number setting field 1103 is made. That is, a configuration is made such that when the numerical value of the AF point number setting field 1103 is “8”, a ninth coordinates cannot be input in the AF point coordinate setting field 1106, and when only seven or fewer coordinates are set, the OK button 1107 cannot be depressed (does not become active) and AF processing cannot be started. The numbers displayed in the AF point coordinate setting field 1106 correspond to the numbers in the AF processing sequence display field 1105.

The operator can press the OK button 1107 if the required items are input in the AF point setting GUI 1100 without contradiction (for example, there are no discrepancies in the numerical values). The Cancel button 1108 can always be depressed, and the operator can cancel the contents that have been input even if an item is being input.

<Out-of-Measurement Area AF Recipe Process Accompanying Update of Focus Distribution During Normal Recipe Process>

FIG. 12 is a flowchart illustrating out-of-measurement-area AF recipe process accompanying update of focus distribution during a normal recipe process, which is different from FIG. 10. An operation entity of each step can be the overall control unit 52 as in the process of FIG. 10.

In step 1201, movement is made to the measurement point, and it is determined whether the measurement point is an AF point which is registered in advance and for which the out-of-measurement area AF processing is to be executed. If it is the AF point, AF processing is executed (step 1203). Focus information obtained by executing AF is acquired (step 1204), and an image for measurement is acquired (step 1205). The image evaluation value of the acquired image and a desired pattern width are measured (step 1206). These processing is repeated for the number of AF points for which the out-of-measurement area AF processing is executed (step 1202), and the focus distribution is calculated from the obtained focus information (step 1207). The threshold value 1 and threshold value 2 are calculated from the image evaluation values and measurement values for a plurality of points (step 1208). In subsequent processing, the recipe process is executed while updating the focus distribution. Movement is made to the next measurement point (step 1201), and a focus control value is calculated and set using the position information and the focus distribution calculated in step 1207 (step 1209). An image is acquired (step 1205), and the image evaluation value and the pattern width are measured (step 1206). When the image evaluation value and the measurement value calculated here are smaller than threshold 1 or threshold 2 calculated in step 1208, AF processing is executed, and the F focus distribution is calculated again based on the focus information (steps 1203 to 1207). When all points are measured, the process ends (step 1210).

### SUMMARY

(i) According to this embodiment, each of the plurality of peripheral AF points (for example, AF points 301 to 304) set outside the measurement area 300 is subjected to autofocusing, and the focus information of the plurality of AF points is acquired. Then, based on these pieces of focus information, the focus distribution within the measurement area 300 is approximated, and using the approximated focus distribution, each measurement point within the measurement area of the same sample as the sample for which the focus information was acquired is measured. Then, when the sample to be measured is changed, focus information of a plurality of AF points is acquired again, the focus distribution (approximate expression) within the measurement area 300 is calculated again, and the sample to be measured is measured. In this way, since the same sample as the sample to be measured is used to create the focus distribution (approximate expression) and measure the measurement area, there is no need to execute autofocus processing in the measurement area, and throughput of measurement processing can be dramatically improved, and high measurement accuracy can be maintained.

(ii) In this embodiment, whether to set the AF point within the measurement area 300 can be determined depending on a type of wafer (whether or not it is susceptible to electrification). By setting the AF point within the measurement area 300 (for example, near the center of the measurement area), it is possible to more accurately approximate the focus distribution within the measurement area 300.

When the operator sets a plurality of AF points around the outside of the measurement area 300, a size of the set region surrounded by the plurality of AF points is calculated. Then, it is determined whether a set number of AF points is sufficient to approximate the focus distribution for measuring the measurement area 300. When the set number of AF points is not appropriate, a notification (on the screen) may be sent to the operator to urge the operator to set more AF points. By doing so, a high accuracy focus distribution (approximate expression) can be calculated.

(iii) When there is an AF point for which focus information cannot be obtained, the focus information may be acquired by executing AF processing on a new AF point (a site where there is a pattern is automatically searched for) within a predetermined pixel range from the AF point. By doing so, it is possible to avoid a situation where the focus distribution within the measurement area 300 cannot be approximated.

(iv) Based on the measurement result of the measurement point within the measurement area 300, the approximated focus distribution may be updated, and the updated focus distribution may be used for measurement of subsequent measurement points after the measurement point. More specifically, an image of the measurement point is obtained from the approximated focus distribution before update, and the image evaluation value and the measurement value are calculated from this image. Then, the image evaluation value is compared with a preset first threshold, and the measurement value is compared with a preset second threshold, and the focus distribution is updated according to the two comparison results. The update of the focus distribution is executed by performing autofocusing on the measurement point to acquire focus information and using the focus information of the measurement point. In this way, the focus distribution is updated when the focus distribution before update is not suitable for measuring the current measurement point, and thus accurate measurement can always be performed using the optimum focus distribution (approximate expression). In addition, the number of execution times of AF processing can be minimized, and thus improvement of throughput is not hindered.

(v) A function of this embodiment can also be realized by a program code of software. In this case, a storage medium having the program code recorded therein is provided to a system or apparatus, and a computer (or CPU or MPU) of the system or apparatus reads the program code stored in the storage medium. In this case, the program code itself read from the storage medium realizes the function of the embodiment described above, and the program code itself and the storage medium storing it form the present disclosure. As a storage medium for supplying such a program code, for example, a flexible disk, a CD-ROM, a DVD-ROM, a hard disk, an optical disk, a magneto-optical disk, a CD-R, a magnetic tape, a non-volatile memory card, a ROM, and the like are used.

Further, based on an instruction of the program code, an operating system (OS) or the like running on the computer may perform part or all of actual processing, and the function of the embodiment described above may be realized by the processing. Furthermore, after the program code read from the storage medium is written into a memory of the computer, based on the instruction of the program code, a CPU or the like of the computer may perform part or all of actual processing, and the function of the embodiment described above may be realized by the processing.

Furthermore, by distributing the program code of software for realizing the function of the embodiment via a network, the program code of software may be stored in storage means such as the hard disk and memory of the system or apparatus, or a storage medium such as the CD-RW and CD-R, and the computer (or CPU or MPU) of the system or apparatus may read and execute the program code stored in the storage means or the storage medium at the time of use.

The processes and techniques described herein are not inherently related to any particular apparatus and can also be implemented by any combination of suitable components. Furthermore, a dedicated apparatus may be constructed to execute the steps of the method described herein. Various technical elements can be formed by appropriately combining a plurality of components disclosed in this embodiment. For example, some components may be omitted from all components shown in the embodiment. Although the present disclosure has been described with reference to specific examples, all of these are for ease of understanding and not for limitation. A person of ordinary skill in the art will readily appreciate that there are numerous combinations of hardware, software, and firmware suitable for implementing the technique of this disclosure. For example, the described software can implement the technique of the present disclosure in a wide variety of programming or scripting languages, such as assembler, C/C++, perl, Shell, PHP, Java (registered trademark), and the like.

Furthermore, in the embodiment described above, control lines and information lines indicate those considered necessary for explanation, and not all the control lines and information lines are necessarily indicated on the product. All configurations may be interconnected.

Additionally, other implementations of the present disclosure will be apparent to a person of ordinary skill in the art from consideration of the specification and embodiment of the present disclosure disclosed herein. The descriptive contents and specific examples in the specification are only typical, the scope and spirit of this disclosure are indicated by the following claims.

### REFERENCE SIGNS LIST

1: electron source
11: primary electron
12: secondary electron with high elevation angle
13: secondary electron with low elevation angle
14: tertiary electron
21: condenser lens
22: upper stage primary electron deflector
23: lower stage primary electron deflector
24: upper stage scanning deflector
25: lower stage scanning deflector
26: rear stage acceleration electrode
27: objective lens
31: lower secondary electron deflector
32: upper secondary electron deflector
33: secondary electron diaphragm
34: upper detector
35: lower detector
41: sample
42: stage
43: stage conveyance base
44: position detection unit
45: position detection laser
51: length measurement SEM device
52: overall control unit
53: signal processing unit
54: deflector control processing unit
55: input and output unit
56: storage unit

1. A charged particle beam system comprising:
a charged particle beam device including a detector configured to detect a signal particle obtained by irradiating a sample with a charged particle beam; and
a computer system that controls an operation of the charged particle beam device, wherein
the computer system executes
a process of performing autofocus on each of a plurality of peripheral AF points set in the sample and outside a measurement area, and acquiring focus information of the plurality of peripheral AF points,
a process of approximating focus distribution within the measurement area based on the focus information of the plurality of peripheral AF points, and
a process of measuring each measurement point within the measurement area of the same sample as the sample from which the focus information is acquired, using the approximated focus distribution.

2. The charged particle beam system according to claim 1, wherein
the computer system further executes a process of performing autofocusing on at least one internal AF point set within the measurement area and acquiring focus information of the at least one internal AF point, and
in the process of approximating the focus distribution, the computer system approximates the focus distribution within the measurement area based on the focus information of the plurality of peripheral AF points and the focus information of the at least one internal AF point.

3. The charged particle beam system according to claim 1, wherein
the computer system executes the process of acquiring the focus information of the plurality of peripheral AF points and the process of approximating the focus distribution within the measurement area each time a sample to be measured changes.

4. The charged particle beam system according to claim 1, wherein
the charged particle beam device comprises a first deflector configured to deflect the charged particle beam, and
the computer system applies coordinates of the measurement point to the approximated focus distribution to calculate a focus parameter, and applies the focus parameter to the first deflector to measure the measurement point.

5. The charged particle beam system according to claim 1, wherein
the computer system calculates a size of a set region surrounded by the plurality of peripheral AF points, and determines whether or not the set number of peripheral AF points is appropriate based on the size of the set region.

6. The charged particle beam system according to claim 5, wherein
when the set number of peripheral AF points is not appropriate, the computer system outputs a notification urging setting of further peripheral AF points.

7. The charged particle beam system according to claim 1, wherein
when an AF point for which the process of acquiring the focus information has failed is present, the computer system acquires focus information of an AF point within a predetermined pixel range from the failed AF point.

8. The charged particle beam system according to claim 1, wherein
the computer system updates the approximated focus distribution based on a measurement result of the measurement point within the measurement area, and uses the updated focus distribution for measurement of measurement points subsequent to the measurement point.

9. The charged particle beam system according to claim 8, wherein
the computer system executes
a process of acquiring an image of the measurement point using the approximated focus distribution before update,
a process of calculating an image evaluation value and a measurement value from the acquired image, and
a process of comparing the image evaluation value with a first threshold and comparing the measurement value with a second threshold, respectively, and updating the focus distribution according to the two comparison results.

10. The charged particle beam system according to claim 9, wherein
in the process of updating the focus distribution, the computer system acquires focus information by performing autofocusing on the measurement point, and updates the focus distribution using the focus information of the measurement point.

11. The charged particle beam system according to claim 1, wherein
the computer system displays a user interface on a screen of a display unit for setting and inputting the peripheral AF points by an operator.

12. The charged particle beam system according to claim 2, wherein
the computer system displays a user interface on a screen of a display unit for setting and inputting the peripheral AF points and the internal AF point by an operator.
